(19) United States
(12) Patent Application Publication
(10) Pub. No.: US 2023/0043973 A1
(43) Pub. Date: Feb. 9, 2023

(54) SEMICONDUCTOR MEMORY DEVICE AND METHOD OF FORMING SEMICONDUCTOR DEVICE

(71) Applicant: Fujian Jinhua Integrated Circuit Co., Ltd., Quanzhou City (CN)

(72) Inventor: Li-Wei Feng, Quanzhou City (CN)

(73) Assignee: Fujian Jinhua Integrated Circuit Co., Ltd., Quanzhou City (CN)

(21) Appl. No.: 17/513,907

(22) Filed: Oct. 29, 2021

(30) Foreign Application Priority Data
Aug. 4, 2021 (CN) 202110891793.0
Aug. 4, 2021 (CN) 202121808799.9

(51) Int. Cl. H01L 27/108

(52) U.S. Cl. CPC H01L 27/10844; H01L 27/10814

(57) ABSTRACT

The disclosure provides a semiconductor memory device and a method of forming a semiconductor device. The semiconductor memory device includes a substrate and a first pattern. The first pattern is disposed on the substrate and extends along a first direction. The first pattern includes an extension portion and two end portions. The two end portions include a first end pattern and a second end pattern, respectively. The extension portion has a first width. The first end pattern includes an outer widened portion and an inner widened portion. The maximum width of the outer widened portion and the maximum width of the inner widened portion are different from each other, and both are greater than the first width of the extension portion of the first pattern.

### BACKGROUND OF THE INVENTION

### 1. Field of the Invention

The present disclosure relates generally to the technical field of semiconductor manufacturing, and more particularly to a semiconductor memory device fabricated by a multiple patterning process and a method of forming a semiconductor device.

### 2. Description of the Prior Art

In the semiconductor manufacturing processes, tiny patterns with precise dimensions are formed in a suitable substrate or material layers such as a semiconductor substrate, film layers, dielectric material layers, or metal material layers by using photolithography and etching processes. To achieve the goal of forming tiny patterns, in the existing semiconductor technology, a mask layer is formed on the target material layer so that firstly, a pattern is formed in the mask layer to define these tiny patterns, and then the pattern of the mask layer is transferred to the target material layer. In general, the mask layer is, for example, a patterned photoresist layer formed by a photolithography process, and/or a patterned mask layer formed by using the patterned photoresist layer.

The dimensions of these tiny patterns continue to decrease with the complexity of integrated circuits. The equipment and patterning methods used to form tiny feature patterns must meet the strict requirements of the resolution of the manufacturing processes and the overlay accuracy. The single patterning method has been unable to meet the resolution requirements or manufacturing process requirements for forming patterns with tiny line width. Therefore, how to improve the existing manufacturing processes of these tiny patterns is one of the important issues in the field.

### SUMMARY OF THE INVENTION

The present disclosure provides a semiconductor memory device and a method of forming a semiconductor device. By using a self-aligned multiple patterning (SAMP) process and different mask patterns to perform a patterning process of a material layer, mutual parallel and alternately arranged material patterns are formed. Two end portions of each material pattern include asymmetric end patterns, and one end pattern of each material pattern includes at least two widened portions. Using at least two widened portions to connect with an extension portion of the material pattern, the reliability of the connection between the end pattern and the extension portion of the material pattern may be improved.

According to an embodiment of the present disclosure, a semiconductor memory device is provided and includes a substrate and a first pattern. The first pattern is disposed on the substrate and extends along a first direction. The first pattern includes an extension portion and two end portions. The two end portions include a first end pattern and a second end pattern, respectively, where the extension portion has a first width, the first end pattern includes an outer widened portion and an inner widened portion, and the maximum width of the outer widened portion and the maximum width of the inner widened portion are different from each other and are both greater than the first width of the extension portion of the first pattern.

According to an embodiment of the present disclosure, a method of forming a semiconductor device is provided and includes the following steps. A substrate is provided and a material layer is formed on the substrate. The material layer includes opposite first and second sides, where the material layer includes a plurality of protruding portions on the first side. A plurality of strip-shaped masks is formed on the material layer, where a partial region of one of the plurality of strip-shaped masks covers a partial region of one of the plurality of protruding portions. A mask layer is formed on the plurality of strip-shaped masks, and the mask layer includes an opening, where the edge of the opening on the first side includes a plurality of mask protruding portions, and each of the mask protruding portions covers the partial region of the strip-shaped mask and the partial region of the protruding portion. The plurality of strip-shaped masks and the mask layer are used as an etching mask, and the material layer is etched.

The embodiments of the present disclosure may form feature patterns with relatively dense layout and relatively small dimensions under the premise of simplifying the processes. Moreover, the reliability of the electrical connection between the formed feature patterns such as a wire and a contact pad pattern may also be enhanced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1, FIG. 2, FIG. 3, FIG. 4, FIG. 5 and FIG. 6 are schematic top views of various stages of a method of forming a semiconductor device according to an embodiment of the present disclosure.

FIG. 7 is a schematic top view of a first pattern and a second pattern of a semiconductor memory device according to an embodiment of the present disclosure.

FIG. 8 is a schematic partial enlarged top view of a first pattern according to another embodiment of the present disclosure.

FIG. 9 is a schematic partial enlarged top view of a first pattern according to yet another embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed indirect contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Although the disclosure is described with respect to specific embodiments, the principles of the disclosure, as defined by the claims appended herein, may obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

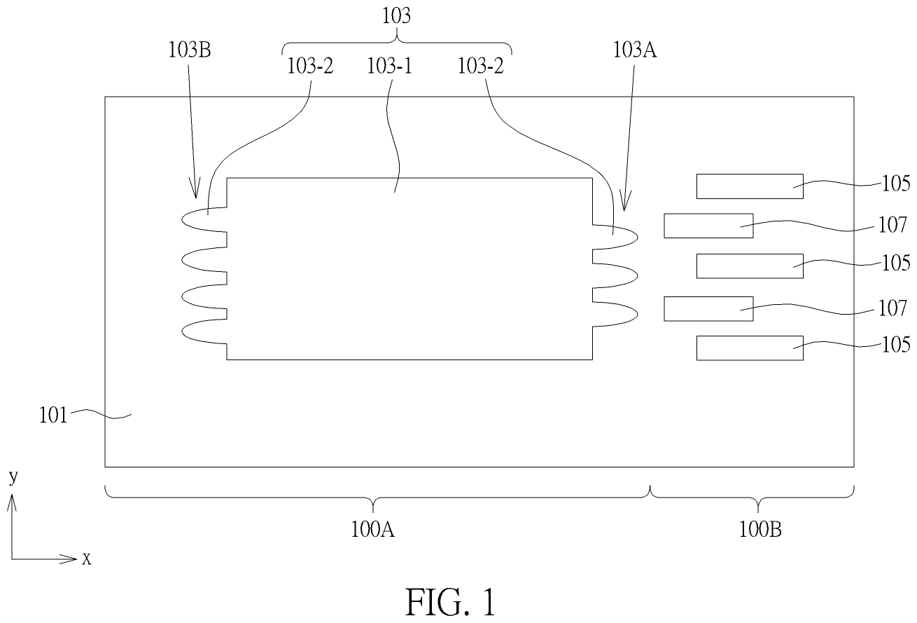

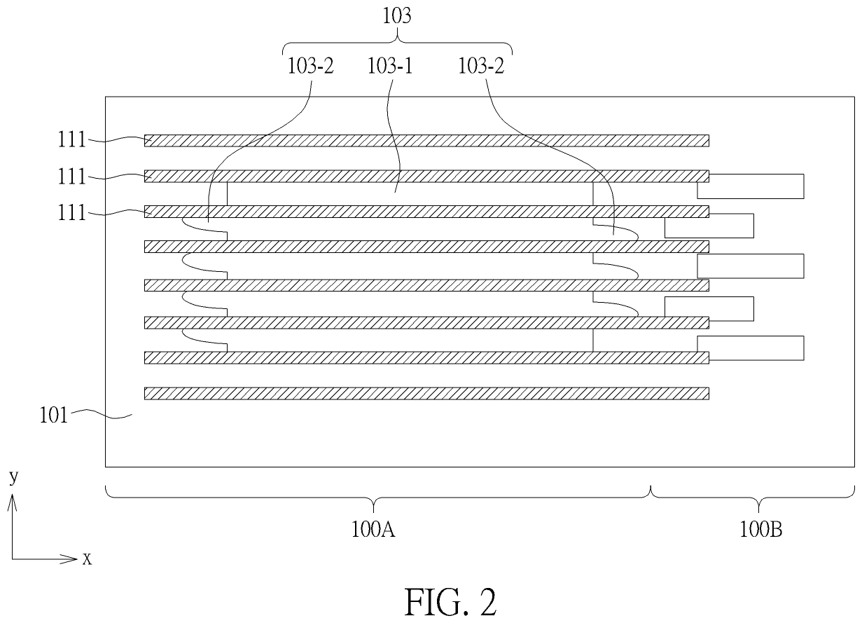

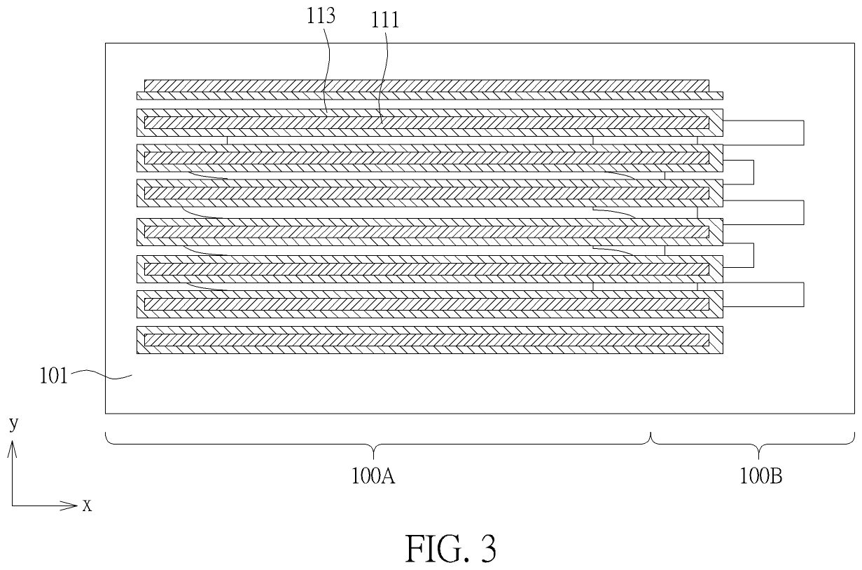

Please refer to FIG. 1 to FIG. 6, which illustrate schematic top views of various stages of a method of forming a semiconductor device according to an embodiment of the present disclosure. First, as shown in FIG. 1, a substrate 101 is provided. The substrate 101 is, for example, a silicon substrate, a silicon-on-insulator (SOI) substrate or other semiconductor substrates. The substrate 101 may include a first region 100A and a second region 100B. The first region 100A is, for example, a device region for disposing memory cells, and the second region 100B is, for example, a peripheral region for disposing logic cells, but not limited thereto. A material layer 103 is formed on the first region 100A of the substrate 101. The material layer 103 includes a main portion 103-1 and a plurality of protruding portions 103-2, where the main portion 103-1 includes opposite first and second edges, and the protruding portions 103-2 are disposed on the first edge and the second edge of the main portion 103-1. In other words, the material layer 103 includes opposite first side 103A and second side 103B, and the protruding portions 103-2 of the material layer 103 are disposed on the first side 103A and the second side 103B, where each of the protruding portions 103-2 located on the first side 103A and each of the protruding portions 103-2 located on the second side 103B do not overlap with each other in a first direction (for example, the x direction shown in FIG. 1).

In addition, a plurality of first block patterns 105 and a plurality of second block patterns 107 that are parallel to each other and extend along the first direction (for example, the x direction shown in FIG. 1) are formed on the second region 100B of the substrate 101. The first block patterns 105 and the second block patterns 107 are arranged alternately and staggered in a second direction (for example, the y direction shown in FIG. 1), and the second direction is perpendicular to the first direction. In one embodiment, the material layer 103, the first block patterns 105 and the second block patterns 107 may be formed by the same photolithography process, and include the same material, for example, they all include a conductive material, such as tungsten. (W), aluminum (Al) or copper (Cu), or other low-resistance metal materials, or further include a dielectric material disposed under the conductive material, such as silicon oxide, silicon nitride (SiN), silicon oxynitride (SiON) or silicon carbonitride (SiCN), but not limited thereto. Moreover, in one embodiment, the material layer 103, the first block patterns 105 and the second block patterns 107 may be directly formed on the substrate 101, but the arrangements of the semiconductor devices of the present disclosure are not limited thereto. In another embodiment, other film layers or components, such as a dielectric layer (not shown), may be further disposed between the material layer 103 and the substrate 101 according to actual component requirements. Furthermore, in order to protect the top surfaces of the material layer 103, the first block patterns 105 and the second block patterns 107, a protective layer (not shown), such as silicon oxide, silicon nitride (SiN), silicon oxynitride (SiON) or silicon carbonitride (SiCN), but not limited thereto, may be disposed on the top surfaces of the material layer 103, the first block patterns 105 and the second block patterns 107, respectively. The protective layer may have the same outlines as these of the material layer 103, the first block patterns 105, and the second block patterns 107 correspondingly disposed thereunder, and the protective layer will be removed at an appropriate stage in the fabrication processes. In order to make the present disclosure easy to understand, the above-mentioned protective layer is not shown in FIG. 1.

Next, referring to FIG. 2, a plurality of strip-shaped mandrels 111 is formed on the material layer 103, and a partial region of one of the strip-shaped mandrels 111 covers a partial region of one of the protruding portions 103-2, and the strip-shaped mandrels 111 also cover the main portion 103-1 of the material layer 103 on the first region 100A. In addition, the strip-shaped mandrels 111 may also extend to the second region 100B along the first direction (for example, the x direction shown in FIG. 2). In one embodiment, the strip-shaped mandrels 111 may be formed of photoresist. A photoresist layer is firstly coated on the material layer 103, and then the strip-shaped mandrels 111 are formed by a photolithography process. In addition, the strip-shaped mandrels 111 may be formed by transferring the pattern of the photoresist layer to the layer below the photoresist layer.

Then, referring to FIG. 3, a spacer 113 is formed on the sidewalls of each strip-shaped mandrel 111. The material of the spacer 113 may be a mask material, such as silicon oxide, silicon nitride (SiN), or silicon oxynitride (SiON) or silicon carbonitride (SiCN), etc. The spacer 113 maybe formed by depositing a mask material layer on the material layer 103 to cover the strip-shaped mandrels 111 and fill the gaps between the strip-shaped mandrels 111, and then using an etching process to remove the mask material covering the top surfaces of the strip-shaped mandrels 111, and remove a part of the mask material between the strip-shaped mandrels 111, leaving the spacer 113 on the sidewalls of each strip-shaped mandrel 111, as shown in FIG. 3, the spacer 113 surrounds each strip-shaped mandrel 111. According to the embodiments of the present disclosure, the width of the spacer 113 is smaller than the width of the strip-shaped mandrel 111, so the size of the spacer 113 in a certain dimension may be a sub-lithographic size.

Next, referring to FIG. 4, each strip-shaped mandrel 111 is removed to leave the spacer 113 on the material layer 103. In the following description, the spacer 113 may also be referred to as strip-shaped masks 113. In one embodiment, each strip-shaped mandrel 111 may be removed by an etching process. As shown in FIG. 4, a partial region of one of the strip-shaped masks 113 covers a partial region of one of the protruding portions 103-2, and each protruding portion 103-2 is disposed corresponding to each strip-shaped mask 113, and two adjacent strip-shaped masks 113 constitute a part of a ring-shaped mask 114. In addition, a partial region of one of the two adjacent strip-shaped masks 113 of the ring-shaped mask 114 covers a partial region of one protruding portion 103-2 on the first side 103A, and a partial region of the other strip-shaped mask 113 of the ring-shaped mask 114 covers a partial region of another protruding portion 103-2 on the second side 103B.

Then, referring to FIG. 5, a mask layer 115 is formed on the strip-shaped masks 113, and the mask layer 115 includes an opening 116. As shown in FIG. 5, the edge 116E of the opening 116 is separated from the edge of the main portion 103-1 of the material layer 103 by a distance, that is, the edge of the main portion 103-1 is separated from the edge 116E of the opening 116. According to the embodiments of the present disclosure, the mask layer 115 further includes a plurality of mask protruding portions 115P disposed on the edge 116E of the opening 116 on the first side 103A and the edge 116E of the opening 116 on the second side 103B. Each mask protruding portion 115P on the first side 103A and each mask protruding portion 115P on the second side 103B do not overlap with each other in the first direction (for example, the x direction shown in FIG. 5). In addition, each mask protruding portion 115P covers a partial region of the strip-shaped mask 113 and a partial region of the protruding portion 103-2. According to the embodiments of the present disclosure, the top-view area of each protruding portion 103-2 is larger than the top-view area of each mask protruding portion 115P. In one embodiment, the mask layer 115 may be formed of a photoresist. The mask layer 115 is formed by a photolithography process, and includes the opening 116 and the mask protruding portions 115P.

Thereafter, referring to FIG. 5 and FIG. 6, the strip-shaped masks 113 and the mask layer 115 (including the opening 116 and the mask protruding portions 115P) of FIG. 5 are used as an etching mask, and the material layer 103 is etched to form a plurality of patterns 120 of a semiconductor device 100 as shown in FIG. 6. In one embodiment, the semiconductor device 100 is a semiconductor memory device. As shown in FIG. 6, the semiconductor memory device includes a substrate 101, and the patterns 120 include a plurality of first patterns 121 and a plurality of second patterns 122 disposed on the substrate 101. The first patterns 121 and the second patterns 122 respectively extend along a first direction (for example, the x direction shown in FIG. 6), and the first patterns 121 and the second patterns 122 are alternately arranged along a second direction (for example, the y direction shown in FIG. 6), where the second direction is not parallel to the first direction, for example, the second direction may be perpendicular to the first direction. Each first pattern 121 has a first end pattern 121P-1 at the end portion on the first side 120A of the pattern 120, and each second pattern 122 has a fourth end pattern 122P-2 at the end portion on the second side 120B of the pattern 120. The first end patterns 121P-1 and the fourth end patterns 122P-2 are arranged asymmetrically, that is, each first end pattern 121P-1 located on the first side 120A and each fourth end patterns 122P-2 located on the second side 120B are not overlapped with each other in the first direction (for example, the x direction shown in FIG. 6). For the case where a protective layer (not shown) is disposed on the top surfaces of the first patterns 121, the second patterns 122, the first block patterns 105, and the second block patterns 107, the protective layer may be removed later, and then conductive plugs 130 electrically connected to the first patterns 121, the second patterns 122, the first block patterns 105, and the second block patterns 107 are formed.

In one embodiment, each first pattern 121 and each second pattern 122 of the semiconductor memory device are respectively bit line patterns having a conductive layer, and each conductive plug 130 of the semiconductor memory device is disposed on each first end pattern 121P-1 and each fourth end pattern 122P-2. In addition, each conductive plug 130 is also disposed on each first block pattern 105 and each second block pattern 107 in the second region 100B.

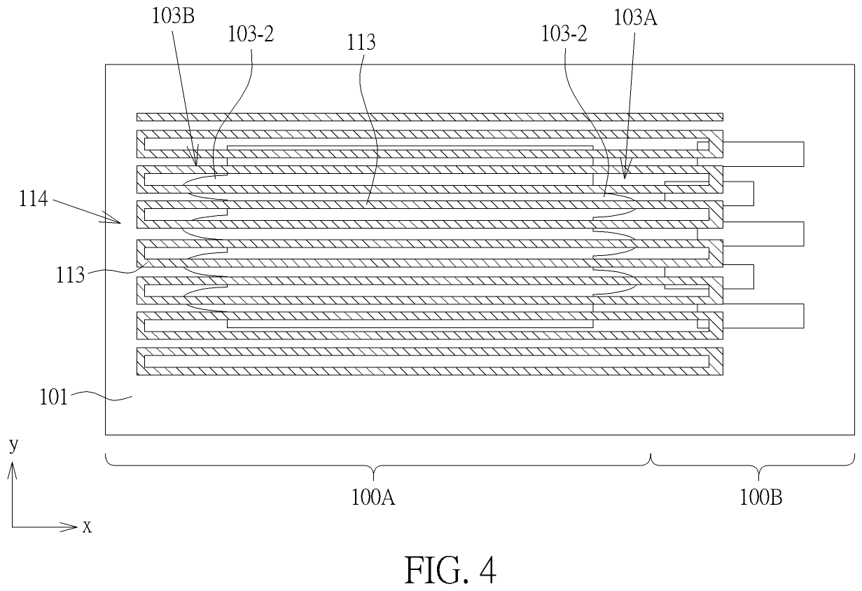

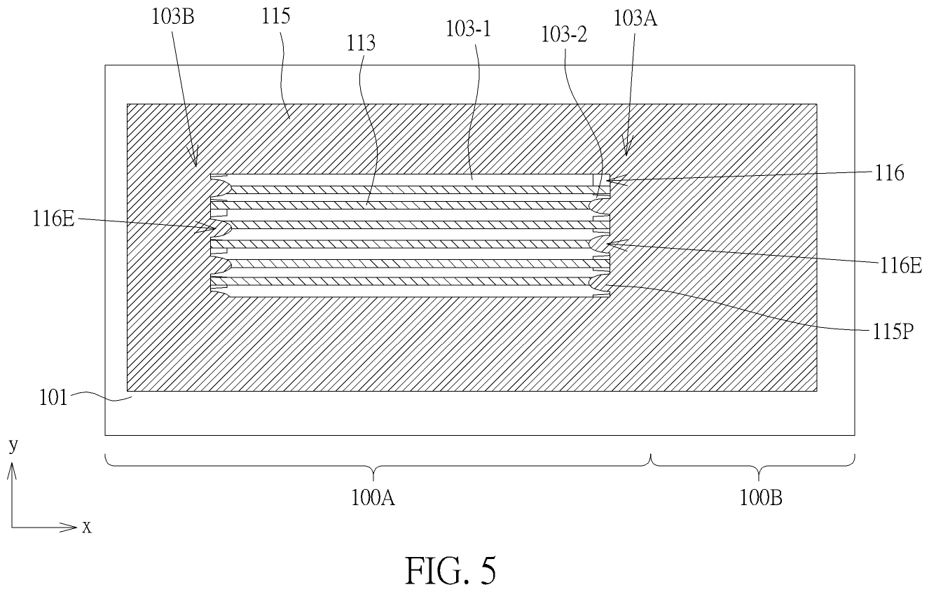

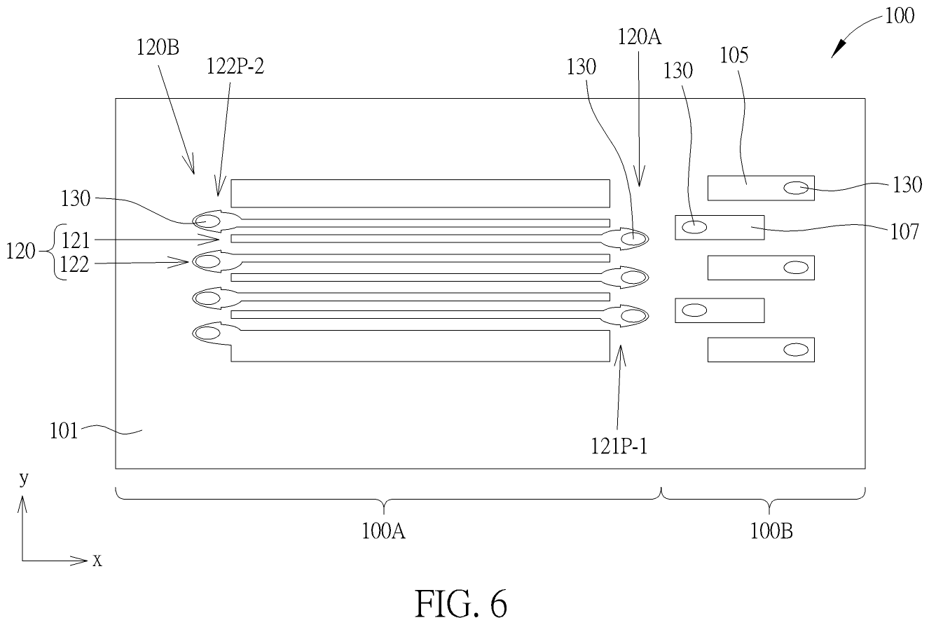

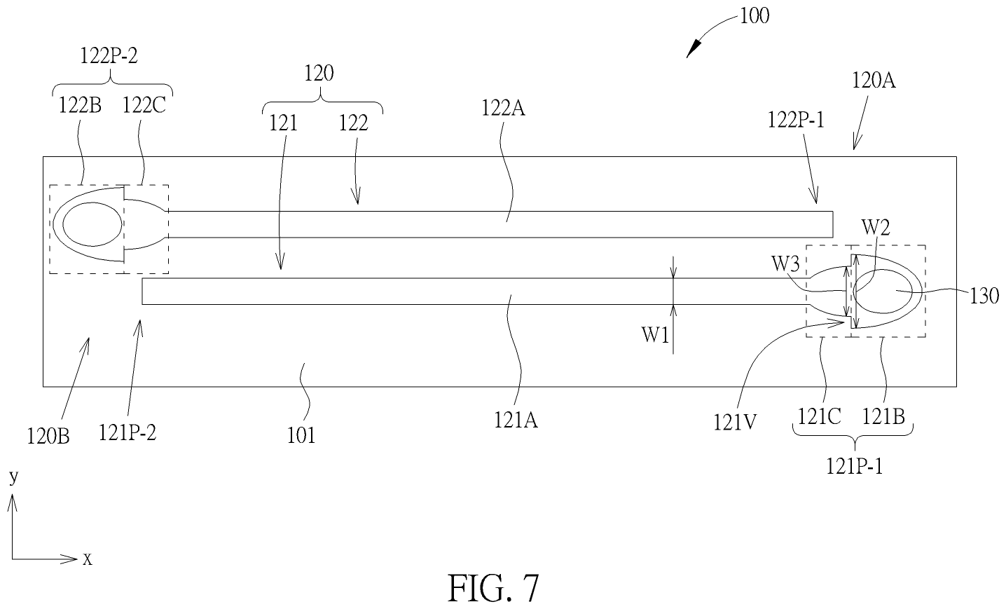

Please refer to FIG. 7, which illustrates a schematic top view of a first pattern and a second pattern of the semiconductor memory device according to an embodiment of the present disclosure. As shown in FIG. 7, the first pattern 121 includes an extension portion 121A and two end portions. The two end portions include a first end pattern 121P-1 and a second end pattern 121P-2, respectively. The first end pattern 121P-1 includes an outer widened portion 121B and an inner widened portion 121C. The first end pattern 121P-1 further includes an end surface 121V perpendicular to the first direction (for example, the x direction shown in FIG. 7), where the end surface 121V is located between the outer widened portion 121B and the inner widened portion 121C. Both the outer widened portion 121B and the inner widened portion 121C include curved surfaces. In addition, according to the embodiments of the present disclosure, the top-view area of the outer widened portion 121B is larger than the top-view area of the inner widened portion 121C. Each conductive plug 130 overlaps the outer widened portion 121B. In one embodiment, the outer widened portion 121B directly contacts the inner widened portion 121C. In addition, the extension portion 121A has a maximum width, that is, a first width W1. The outer widened portion 121B has a maximum width, that is, a second width W2, and the inner widened portion 121C has a maximum width, that is, a third width W3. According to an embodiment of the present disclosure, the second width W2 of the outer widening portion 121B and the third width W3 of the inner widening portion 121C are different from each other. Both the second width W2 and the third width W3 are greater than the first width W1 of the extension portion 121A. In addition, the second width W2 of the outer widened portion 121B is greater than the third width W3 of the inner widened portion 121C.

Similarly, the second pattern 122 includes an extension portion 122A and two end portions. The two end portions respectively include a third end pattern 122P-1 on the first side 120A and a fourth end pattern 122P-2 on the second side 120B. As shown in FIG. 7, the third end pattern 122P-1 of the second pattern 122 overlaps a partial region of the inner widened portion 121C of the first pattern 121 in a second direction (for example, the y direction shown in FIG. 7). The partial region may also be referred to as an overlapping region. The second direction is not parallel to the first direction, for example, the second direction may be perpendicular to the first direction. In addition, other partial region of the inner widened portion 121C of the first pattern 121, that is, a partial region that does not overlap with the third end pattern 122P-1 of the second pattern 122 (also referred to as a non-overlapping region) is arranged between the above-mentioned overlapping region of the inner widened portion 121C and the outer widened portion 121B. The other partial region (non-overlapping region) of the inner widened portion 121C is separated from the third end pattern 122P-1 of the second pattern 122 in the first direction (for example, the x direction shown in FIG. 7).

As shown in FIG. 7, in one embodiment, the fourth end pattern 122P-2 of the second pattern 122 on the second side 120B includes an outer widened portion 122B and an inner widened portion 122C. The top-view area of the outer widened portion 122B is larger than the top-view area of the inner widened portion 122C. In addition, the maximum width of the outer widened portion 122B is greater than the maximum width of the inner widened portion 122C. In one embodiment, the outer widened portion 122B directly contacts the inner widened portion 122C.

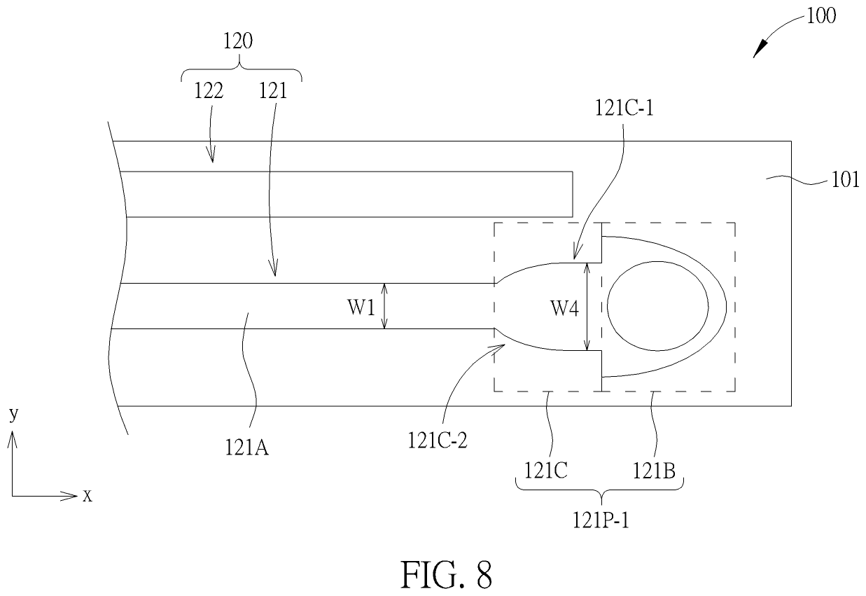

Please refer to FIG. 8, which illustrates a partial enlarged top view of a first pattern according to another embodiment of the present disclosure. The difference between the first pattern 121 of FIG. 8 and the first pattern 121 of FIG. 7 is that a partial region 121C-1 where the inner widened portion 121C directly contacts the outer widened portion 121B has a fixed width, that is, a fourth width W4. A partial region 121C-2 where the inner widened portion 121C directly contacts the extension portion 121A has a gradual width. The width of the partial region 121C-2 is gradually decreased from the fourth width W4 of the partial region 121C-1 to the first width W1 of the extension portion 121A in the direction from the outer widened portion 121B to the extension portion 121A.

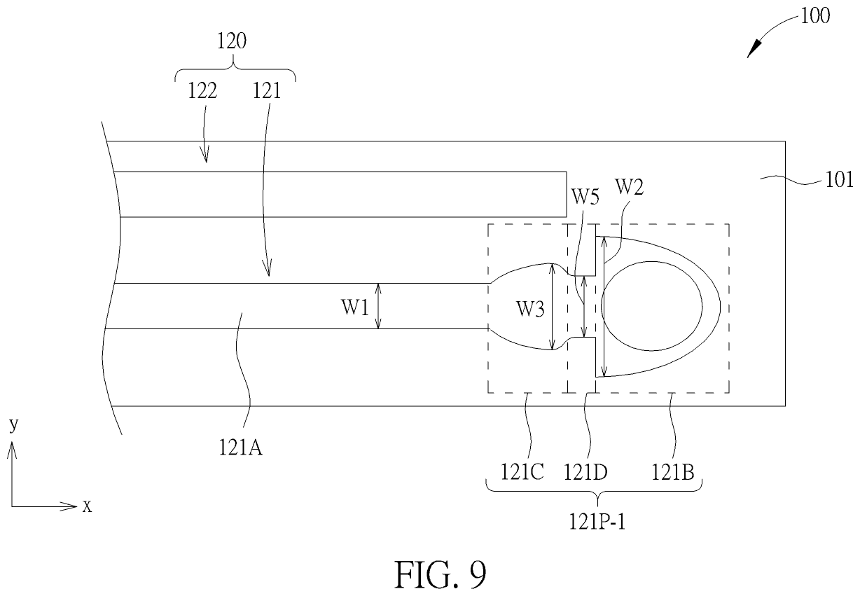

Please refer to FIG. 9, which illustrates a partial enlarged top view of a first pattern according to yet another embodiment of the present disclosure. The difference between the first pattern 121 of FIG. 9 and the first pattern 121 of FIG. 7 is that a connecting portion 121D is further disposed between the inner widened portion 121C and the outer widened portion 121B. The connecting portion 121D has a maximum width, that is, a fifth width W5. The fifth width W5 of the connecting portion 121D is greater than the first width W1 of the extension portion 121A. In one embodiment, the fifth width W5 of the connecting portion 121D may be smaller than the second width W2 of the outer widened portion 121B, and also smaller than the third width W3 of the inner widened portion 121C. In another embodiment, the fifth width W5 of the connecting portion 121D may be smaller than the second width W2 of the outer widened portion 121B, and greater than the third width W3 of the inner widened portion 121C.

The structures illustrated in the above-mentioned FIG. 6 to FIG. 9 only show a part of the semiconductor device or the semiconductor memory device of the present disclosure. The semiconductor device or the semiconductor memory device may also include other components and structures to thereby achieve the functions of the semiconductor device or the semiconductor memory device. For example, when the semiconductor device or the semiconductor memory device is a dynamic random access memory (DRAM), the substrate 101 may also include a plurality of active regions (not shown), which are surrounded by an isolation structure (not shown), for example, surrounded by a shallow trench isolation (STI) structure, and the active regions are disposed below the bit line patterns (consisting of each first pattern 121 and each second pattern 122). Each active region may be electrically connected to the corresponding bit line pattern through a bit line plug (not shown). The substrate 101 may further include a plurality of word line patterns (not shown in the figures), which may extend along the second direction y and pass through corresponding active regions. The semiconductor device or the semiconductor memory device may also include a plurality of capacitor structures (not shown) disposed above the substrate 101. The capacitor structures may be respectively electrically connected to one end of the active region in the substrate 101 for storing charges from the bit lines. It should be noted that the above dynamic random access memory is only one aspect of the present disclosure. Without departing from the concept of the present disclosure, the semiconductor device or semiconductor memory device may also be any other typed semiconductor device or semiconductor memory device.

According to the embodiments of the present disclosure, the patterning process of the material layer may be performed by a self-aligned multiple patterning (SAMP) process and different mask patterns to form a plurality of first patterns 121 and a plurality of second patterns 122 with relatively dense layout and relatively small dimension. The first patterns 121 and the second patterns 122 maybe used as wires, for example, bit lines of a semiconductor memory device. In addition, asymmetric first end pattern 121P-1 and fourth end pattern 122P-2 are respectively formed at the end portion of each first pattern 121 on the first side 120A and at the end portion of each second pattern 122 on the second side 120B. Each of the first end patterns 121P-1 and each of the fourth end patterns 122P-2 both include the outer widened portion and the inner widened portion, which maybe used as contact pads for wires. The outer widened portion with a larger top-view area and a larger maximum width may be used to dispose the conductive plug 130 thereon, thereby improving the reliability of the electrical connection between the conductive plug and the contact pad. The inner widened portion may increase the reliability of the connection between the outer widened portion and the extension portion. Meanwhile, the inner widened portion with a smaller maximum width may also avoid or reduce a short circuit problem which may be caused by the first end pattern 121P-1 of the first pattern 121 being in contact with the third end pattern 122P-1 of the adjacent second pattern 122. Therefore, the embodiments of the present disclosure may form wires and contact pad patterns with high reliability of electrical connection, relatively dense layout, and relatively small dimensions under the premise of simplifying the processes, thereby improving the yield of semiconductor devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor memory device, comprising:
a substrate; and
a first pattern, disposed on the substrate and extending along a first direction, wherein the first pattern comprises an extension portion and two end portions, the two end portions comprises a first end pattern and a second end pattern, respectively, and wherein the extension portion has a first width, the first end pattern comprises an outer widened portion and an inner widened portion, and a maximum width of the outer widened portion and a maximum width of the inner widened portion are different from each other and both greater than the first width of the extension portion of the first pattern.

2. The semiconductor memory device of claim 1, wherein the first end pattern comprises an end surface perpendicular to the first direction.

3. The semiconductor memory device of claim 1, wherein the maximum width of the outer widened portion is greater than the maximum width of the inner widened portion.

4. The semiconductor memory device of claim 1, further comprising a plurality of second patterns, each extending along the first direction, wherein the plurality of second patterns and the plurality of first patterns are alternately arranged along a second direction, and each of the second patterns comprises an end portion on a first side, the end portion of each of the second patterns overlaps a partial region of the inner widened portion in the second direction, and the second direction is not parallel to the first direction.

5. The semiconductor memory device of claim 4, wherein other partial region of the inner widened portion is disposed between the partial region of the inner widened portion and the outer widened portion, and the other partial region of the inner widened portion is separated from the end portion of the second pattern in the first direction.

6. The semiconductor memory device of claim 4, wherein each of the second patterns comprises another end portion disposed on a second side, the another end portion comprises an outer widened portion and an inner widened portion, and a maximum width of the outer widened portion of the second pattern is greater than a maximum width of the inner widened portion of the second pattern.

7. The semiconductor memory device of claim 1, wherein the outer widened portion directly contacts the inner widened portion.

8. The semiconductor memory device of claim 1, wherein the outer widened portion and the inner widened portion both comprise curved surfaces.

9. The semiconductor memory device of claim 1, wherein a top-view area of the outer widened portion is larger than a top-view area of the inner widened portion.

10. The semiconductor memory device of claim 1, wherein each of the first patterns and each of the second patterns are bit line patterns having a conductive layer.

11. The semiconductor memory device of claim 1, further comprising a plurality of conductive plugs, wherein each of the plurality of conductive plugs overlaps the outer widened portion.

12. A method of forming a semiconductor device, comprising:
providing a substrate;
forming a material layer on the substrate, wherein the material layer comprises a first side and a second side opposite to each other, and the material layer comprises a plurality of protruding portions on the first side;
forming a plurality of strip-shaped masks on the material layer, wherein a partial region of one of the plurality of strip-shaped masks covers a partial region of one of the plurality of protruding portions;
forming a mask layer on the plurality of strip-shaped masks, wherein the mask layer comprises an opening, and an edge of the opening on the first side comprises a plurality of mask protruding portions, each of the mask protruding portions covers the partial region of the strip-shaped mask and the partial region of the protruding portion; and
etching the material layer by using the plurality of strip-shaped masks and the mask layer as an etching mask.

13. The method of forming a semiconductor device of claim 12, wherein each of the protruding portions is disposed corresponding to each of the strip-shaped masks.

14. The method of forming a semiconductor device of claim 12, wherein two adjacent strip-shaped masks of the plurality of strip-shaped masks constitute a part of a ring-shaped mask.

15. The method of forming a semiconductor device of claim 12, wherein the material layer further comprises a main portion, the plurality of protruding portions are disposed on an edge of the main portion, and the edge of the main portion is separated from the edge of the opening.

16. The method of forming a semiconductor device of claim 12, wherein a top-view area of each of the protruding portions is larger than a top-view area of each of the mask protruding portions.

17. The method of forming a semiconductor device of claim 12, wherein before forming the plurality of strip-shaped masks, the material layer further comprises a plurality of protruding portions on the second side, and each of the protruding portions on the second side and each of the protruding portions on the first side do not overlap with each other in a first direction.

18. The method of forming a semiconductor device of claim 17, wherein before etching the material layer, the edge of the opening on the second side comprises a plurality of mask protruding portions, and each of the mask protruding portions on the second side and each of the mask protruding portions on the first side do not overlap with each other in the first direction.

19. The method of forming a semiconductor device of claim 12, wherein after the material layer is etched, a plurality of patterns is formed in the material layer, and the plurality of patterns comprises:
a plurality of first patterns, each extending along a first direction, wherein each of the first patterns comprises an extension portion and an end portion on the first side, and the end portion comprises an outer widened portion and an inner widened portion, and a maximum width of the outer widened portion is greater than a maximum width of the inner widened portion; and
a plurality of second patterns, each extending along the first direction, wherein the plurality of second patterns and the plurality of first patterns are alternately arranged along a second direction, and each of the second patterns comprises an end portion on the first side, the end portion of the second pattern overlaps the inner widened portion in the second direction, and the second direction is not parallel to the first direction.

20. The method of forming a semiconductor device of claim 19, wherein the maximum width of the inner widened portion is greater than a maximum width of the extension portion.
